(19) United States
(12) Patent Application Publication
(10) Pub. No.: US 2025/0299753 A1
(43) Pub. Date: Sep. 25, 2025

(54) PRE-PROGRAM ON EDGE WORD LINES FOR IMPROVED MEMORY CELL RETENTION READ WINDOW BUDGET

(71) Applicant: Micron Technology, Inc., Boise, ID (US)

(72) Inventors: Hong-Yan Chen, San Jose, CA (US); Ching-Huang Lu, Fremont, CA (US); Yingda Dong, Los Altos, CA (US)

(73) Assignee: Micron Technology, Inc., Boise, ID (US)

(21) Appl. No.: 19/080,758

(22) Filed: Mar. 14, 2025

Related U.S. Application Data
(60) Provisional application No. 63/569,050, filed on Mar. 22, 2024.

(51) Int. Cl. G11C 16/34; G11C 16/08; G11C 16/10

(52) U.S. Cl. CPC G11C 16/3459; G11C 16/08; G11C 16/102

(57) ABSTRACT

A method for improving data retention of edge QLC word lines of a memory device is provided. The memory device comprises first-type memory cells and second-type memory cells. The first-type memory cells have edge word lines and non-edge word lines. The edge word lines of the first-type memory cells border word lines of the second-type memory cells. The method comprises applying one or more pre-program pulses to the word lines of at least the second-type memory cells such that a lowest level threshold voltage of the second-type memory cells is boosted to reduce a difference between the boosted lowest level threshold voltage of the second-type memory cells and a threshold voltage of the first-type memory cells associated with the edge word lines. The method further comprises applying one or more program pulses and verification pulses to the word lines of the first-type memory cells and the second-type memory cells.

This application claims priority to U.S. Provisional Application No. 63/569,050, filed on Mar. 22, 2024, entitled “PRE-PROGRAM ON EDGE WORD LINES FOR IMPROVED MEMORY CELL RETENTION READ WINDOW BUDGET,” the content of which is incorporated by reference in its entirety for all purposes.

### TECHNICAL FIELD

This disclosure relates to one or more systems for memory, including techniques for improving data retention of edge Quad-Level Cell (QLC) word lines.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIGS. 1A and 1B illustrate an example of a host system and a memory system that support techniques for improving data retention of edge QLC word lines in accordance with examples as disclosed herein.

FIG. 1C is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIG. 2D illustrates an example of a memory device including multiple blocks of memory cells in accordance with examples as disclosed herein.

FIG. 3 is a block diagram of an example apparatus for implementing one or more systems and for performing one or more methods described herein, in accordance with examples as disclosed herein.

FIG. 4 is a block diagram illustrating a word line configuration of a memory block in a memory device in accordance with some embodiments of the present disclosure.

FIG. 5 is a cross-sectional view of three adjacent memory cells in a two-dimensional NAND memory array in accordance with some embodiments of the present disclosure.

FIG. 6 illustrates a Vt distribution chart for four edge MLC word lines of a memory block after a regular programing operation in accordance with some embodiments of the present disclosure.

FIG. 7 illustrates Read Window Budgets of memory cells across all data word lines in a memory array under High Temperature Data Retention test in accordance with some embodiments of the present disclosure.

FIG. 8 illustrates a program sequence applied to MLC memory cells on some edge MLC word lines in a memory array in accordance with some embodiments of the present disclosure.

FIG. 9 illustrates a flowchart showing methods that support techniques for improving data retention of edge QLC word lines in accordance with some embodiments of the present disclosure.

### DETAILED DESCRIPTION

In the realm of modern memory chip design, the complexity and demands placed on memory chips continue to escalate. Memory chips must adhere to various stringent criteria, such as, maintaining a minimum Read Window Budget (RWB). RWB refers to the cumulative margin between threshold voltage levels within a memory cell. In chip design, a larger RWB is preferred as it provides sufficient margins between different voltage thresholds, thereby enabling accurate reading even in the event of excessive charge loss, disturbance, or over-programming.

To provide reliable products, memory chips typically undergo rigorous performance testing, especially under harsh conditions. One such test is the High Temperature Data Retention (HTDR) test. In this test, the memory chip is placed in a 125° C. environment for varying durations, ranging from 1 to 16 hours. The HTDR test requires that after the longest duration of exposure, typically 16 hours, all data word lines on the memory chip must maintain a RWB above a predefined acceptable margin. Failure of a single data word line to meet this criterion may result in the entire chip failing the HTDR test.

It is observed that as the duration of the HTDR test increases, the RWBs of certain edge Quad-Level Cell (QLC) word lines, positioned at the edge of a QLC memory deck, may experience a significant decrease compared to non-edge QLC word lines. This decline poses a significant risk to HTDR test failure. The main reason for this abrupt decrease of RWB in certain edge QLC word lines is due to lateral charge migration (LCM) to adjacent Multi-Level Cell (MLC) word lines.

A new approach aimed at mitigating the LCM charge loss in certain edge QLC word lines is described herein. The new approach involves pre-programming certain neighboring edge MLC word lines to boost the lowest level threshold voltage of the MLC word lines, followed by regular programming of the MLC word lines. By narrowing the voltage differential between the edge MLC word lines and the edge QLC word lines, the technique effectively reduces LCM charge loss, thereby enhancing the RWB on those critical edge QLC word lines.

The disclosed methods offer substantial enhancements in the data retention RWB of certain edge QLC word lines, while streamlining the process for threshold voltage elevation of edge MLC word lines. Moreover, the techniques provide a cost-effective means to improve the data retention capabilities of edge QLC word lines.

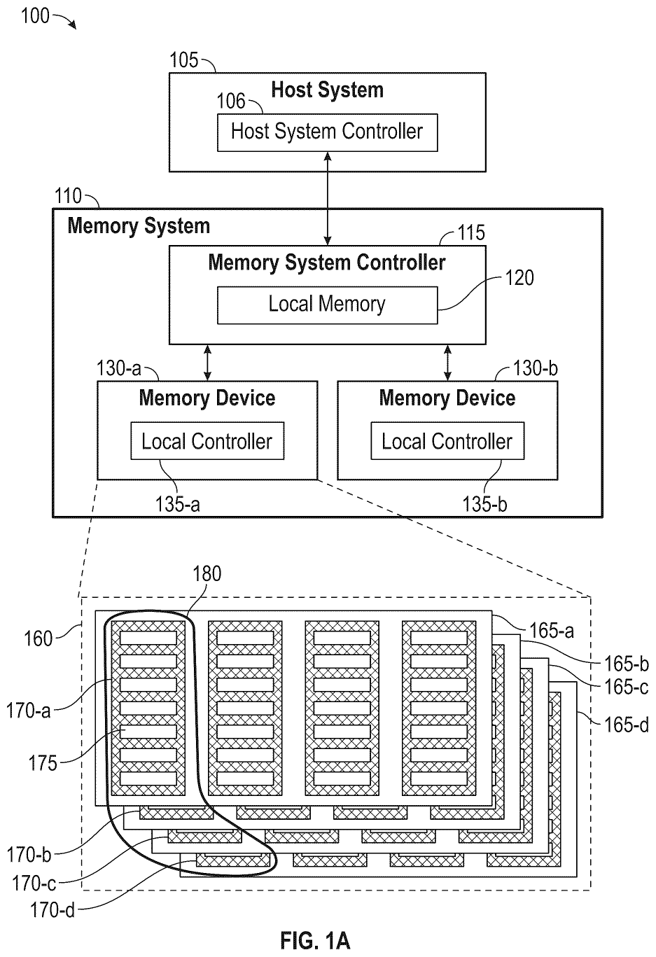

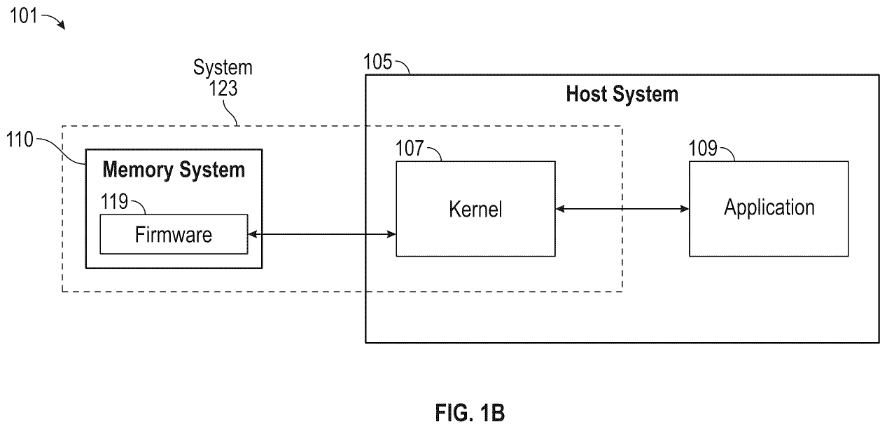

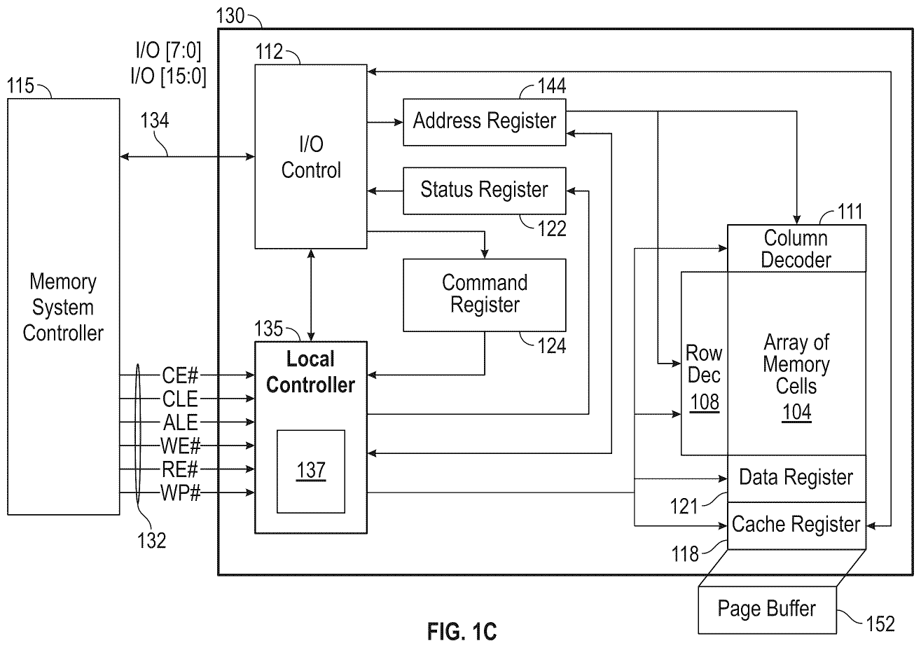

FIG. 1A illustrates an example of a system 100 that supports techniques for improving data retention of edge QLC word lines in accordance with examples as disclosed herein. System 100 includes a host system 105 coupled with a memory system 110. System 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

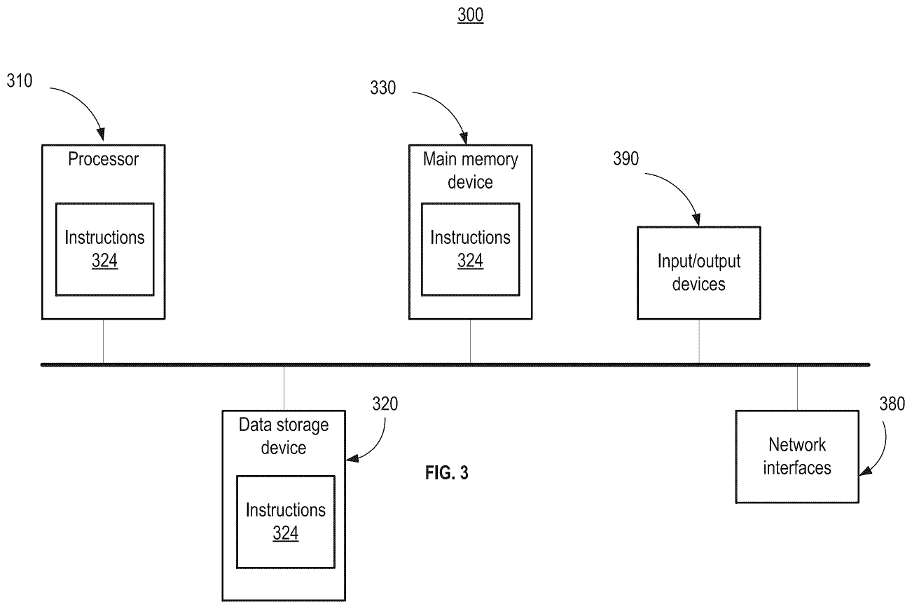

System 100 may include a host system 105, which may be coupled with memory system 110. In some examples, this coupling may include an interface with a host system controller 106, which may be an example of a controller or control component configured to cause host system 105 to perform various operations in accordance with examples as described herein. Host system 105 may include one or more devices and, in some cases, may include a processor chipset and a software stack executed by the processor chipset. Host system 105 may be implemented by, for example, an apparatus 300 shown in FIG. 3. For example, host system 105 may include an application configured for communicating with memory system 110 or a device therein. The processor chipset may include one or more cores, one or more caches (e.g., memory local to or included in host system 105), a memory controller (e.g., NVDIMM controller), and a storage protocol controller (e.g., peripheral component interconnect express (PCIe) controller, serial advanced technology attachment (SATA) controller). Host system 105 may use memory system 110, for example, to write data to memory system 110 and read data from memory system 110. Although one memory system 110 is shown in FIG. 1A, the host system 105 may be coupled with any quantity of memory systems 110.

Host system 105 may be coupled with memory system 110 via at least one physical host interface. Host system 105 and memory system 110 may, in some cases, be configured to communicate via a physical host interface using an associated protocol (e.g., to exchange or otherwise communicate control, address, data, and other signals between memory system 110 and host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a Graphical Double Data Rate (GDDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of host system 105 and a memory system controller 115 of memory system 110. In some examples, host system 105 may be coupled with memory system 110 (e.g., host system controller 106 may be coupled with memory system controller 115) via a respective physical host interface for each memory device 130 included in the memory system 110, or via a respective physical host interface for each type of memory device 130 included in memory system 110.

Memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1A, memory system 110 may include any quantity of memory devices 130. Further, if the memory system 110 includes more than one memory device 130, different memory devices 130 within the memory system 110 may include the same or different types of memory cells.

Memory system controller 115 may be coupled with and communicate with host system 105 (e.g., via the physical host interface) and may be an example of a controller or control component configured to cause memory system 110 to perform various operations in accordance with examples as described herein. Memory system controller 115 may also be coupled with and communicate with memory devices 130 to perform operations such as reading data, writing data, erasing data, or refreshing data at a memory device 130—among other such operations—which may generically be referred to as access operations. In some cases, memory system controller 115 may receive commands from the host system 105 and communicate with one or more memory devices 130 to execute such commands (e.g., at memory arrays within the one or more memory devices 130). For example, memory system controller 115 may receive commands or operations from host system 105 and may convert the commands or operations into instructions or appropriate commands to achieve the desired access of memory devices 130. In some cases, memory system controller 115 may exchange data with host system 105 and with one or more memory devices 130 (e.g., in response to or otherwise in association with commands from host system 105). For example, memory system controller 115 may convert responses (e.g., data packets or other signals) associated with the memory devices 130 into corresponding signals for the host system 105.

Memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from host system 105 and physical addresses (e.g., physical block addresses) associated with memory cells within memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to memory system controller 115. Memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

Memory system controller 115 may also include a local memory 120. In some cases, local memory 120 may include read-only memory (ROM) or other memory that may store operating code (e.g., executable instructions) executable by memory system controller 115 to perform functions ascribed herein to memory system controller 115. In some cases, local memory 120 may additionally, or alternatively, include static random access memory (SRAM) or other memory that may be used by memory system controller 115 for internal storage or calculations, for example, related to the functions ascribed herein to memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same semiconductor die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1A, a memory device 130-a may include a local controller 135-a and a memory device 130-b may include a local controller 135-b. In the examples illustrated in this disclosure (e.g., the example shown in FIG. 1C), local controller 135 is disposed on the same semiconductor die as the memory array (e.g., array 104); and a separate memory system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a memory system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of memory blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of memory blocks 170 and, in some cases, concurrent operations may be performed on different planes 165. For example, concurrent operations may be performed on memory cells within different blocks 170 so long as the different blocks 170 are in different planes 165. In some cases, an individual memory block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line). Example memory cells structures are shown in more detail below using illustrative schematics.

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, L2P (logical-to-physical) mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

System 100 may include any quantity of non-transitory computer readable media that support techniques for logical-to-physical table compression. For example, host system 105 (e.g., a host system controller 106), memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some cases, a memory system 110 may compress an L2P mapping to expand the quantity of physical addresses mapped by the L2P mapping. For example, if a set of consecutive entries of an uncompressed L2P mapping includes consecutive physical addresses, memory system 110 may compress the consecutive entries into a single entry which includes a starting physical address of the consecutive physical addresses. Additionally, memory system 110 may include an indication of a starting logical address corresponding to the starting physical address in the compressed entry. To identify a physical address within the compressed entry, memory system 110 may determine an offset between a logical address corresponding to the physical address (e.g., a logical address included in a read command for data stored at the physical address) and the starting physical address using the indication, and may apply the offset to the starting physical address to determine the physical address. Compressing the L2P mapping may allow the L2P mapping to cover an expanded range of physical address space without increasing the size of the L2P mapping.

FIG. 1B illustrates an example of a system diagram 101 that illustrates communication between host system 105 and memory system 110 via using a kernel and firmware, in accordance with examples as disclosed herein. System diagram 101 may include a memory system 110, a kernel 107, and an application 109. The memory system 110 may include a firmware 119. Firmware 119 may be implemented by a controller and/or other circuitry of the memory system (e.g., memory system controller 115 and/or local controllers 135 shown in FIG. 1A). In some examples, a system 123 as described herein may include memory system 110 and kernel 107. Additionally, a host system 105 may include kernel 107 and the application 109.

As described above, memory system 110 may include multiple memory devices, including non-volatile memory devices and volatile memory devices (e.g., local memory 120), configured to store and retrieve data. Firmware 119 may refer to software stored within a memory array within memory system 110 (e.g., a non-volatile memory device within the memory system 110) and/or a local memory 120 as shown in FIG. 1A. Firmware 119 may provide low-level control functions for the memory system 110. For example, firmware 119 may function as an interface between the memory system 110 and other components of the system 123, and host system 105 may issue access operations to memory system 110 by interfacing with firmware 119. In some examples, firmware 119 may be or be included within or implemented by a memory system controller 115, as described herein with reference to FIG. 1A. In some examples, memory system 110 may store a logical-to-physical mapping that maps logical addresses to physical addresses within a non-volatile memory device (e.g., in a logical-to-physical table). To perform a memory access operation, memory system 110 may move a portion of the logical-to-physical mapping corresponding to one or more logical addresses (e.g., indicated by kernel 107) from the non-volatile memory device to a volatile memory device.

Kernel 107 may function as an interface between host system 105 and components associated with host system 105, such as an operating system of host system 105. Additionally, kernel 107 may perform resource allocation and file management, among other operations, for host system 105. For example, an application 109 running within host system 105 may access information stored within memory system 110 by issuing commands to kernel 107, which may indicate files to be accessed. Kernel 107 may store mapping information associated with the files. For example, a file may be associated with a file name, and may correspond to a range of logical block addresses. Kernel 107 may store mapping information (e.g., a mapping table) that may track logical block addresses corresponding to files of host system 105. In some examples, application 109 may issue an access command to kernel 107 indicating a file name, and offset, and a length associated with a file to be accessed, and kernel 107 may retrieve a one or more logical block addresses corresponding to the file to be accessed. Kernel 107 may then communicate with firmware 119 to indicate the one or more logical block addresses to memory system 110, and memory system 110 may perform an access operation based on the one or more logical block addresses. Memory system 110 may communicate the accessed information to kernel 107 (e.g., via the firmware 119).

In some examples, kernel 107 may communicate with to firmware 119 using information units (e.g., UFS protocol information units (UPIUs)). For example, kernel 107 may issue or receive commands, responses, data, or other information via information units exchanged with the firmware 119. An information unit may refer to a data packet that may contain a header segment and one or more transaction specific fields. In some examples, an information unit may additionally include one or more extended header segments, one or more data segments, or a combination thereof. The header segments of an information unit may indicate information associated with a destination for the information unit, a source of the information unit, a function request, whether additional data or parameters are to be transmitted, whether the additional data or parameters are included within the information unit or to be sent in a following information unit, or any combination thereof. The transaction specific fields may be used for additional fields depending on the operation associated with the information unit. The data segments may be used to include data to be transferred from a device to another.

In some examples, a command information unit (e.g., a command UPIU) may be an example of an information unit associated with the transmission of a command (e.g., an SCSI command) and may indicate a device to perform some operation indicated by the command information unit. For example, the command information unit may include a block descriptor (e.g., a command descriptor block) which may indicate information related to the operation indicated by the command information unit. In some examples, kernel 107 may transfer a command information unit to memory system 110 to indicate memory system 110 of an operation to be performed by memory system 110.

In some examples, to perform an access operation, memory system 110 may load a L2P mapping associated with information to be accessed. For example, memory system 110 may transfer a portion of a logical-to-physical mapping associated with the information to be accessed from a non-volatile memory device of memory system 110 (e.g., NAND memory) to a volatile memory device (e.g., an SRAM) of the memory system 110. In another example, host system 105 may notify memory system 110 of a logical block address range corresponding to an upcoming access operation (e.g., prior to issuing an access command). Memory system 110 may use the logical block address range to load (e.g., pre-load, pre-fetch) an associated portion of a L2P mapping (e.g., from a non-volatile memory device to a volatile memory device) prior to receiving an access command that indicates memory system 110 to perform the access operation. Accordingly, after host system 105 issues the access command, memory system 110 may issue a response to host system 105 faster as memory system 110 has already loaded relevant portions of the L2P mapping associated with the access operation.

The above description of the system diagram 101 are illustrative examples of communication between host system 105 and memory system 110 by using a kernel 107, application 109, and firmware 119. It is understood that additional ways of communication, including function calls, commands, responses, messages, etc. can be implemented using host system 105 and memory system 110, and/or additional systems or components.

FIG. 1C is a simplified block diagram of a memory device 130 in communication with a memory system controller 115 of a memory system (e.g., the memory system 110 of FIGS. 1A and 1B), according to an embodiment. As shown in FIG. 1C and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1C) of at least a portion of the array of memory cells 104 are capable of being programmed to one of at least two target data states for storing any number of bits of information.

With continued reference to FIG. 1C, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external memory system controller 115, i.e., the local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the memory system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to memory system controller 115.

As shown in FIG. 1C, memory device 130 receives various control signals via local controller 135 from memory system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the memory system controller 115 over a multiplexed input/output (I/O) bus 134 and outputs data to the memory system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 144. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1C has been simplified. It should be recognized that the functionality of the various block components described with reference to FIG. 1C may not necessarily be segregated to distinct components or component portions of an integrated circuit device. For example, a single component or component portion of an integrated circuit device could be adapted to perform the functionality of more than one block component of FIG. 1C. Alternatively, one or more components or component portions of an integrated circuit device could be combined to perform the functionality of a single block component of FIG. 1C. Additionally, while specific I/O pins are described in accordance with popular conventions for receipt and output of the various signals, it is noted that other combinations or numbers of I/O pins (or other I/O node structures) can be used in the various embodiments.

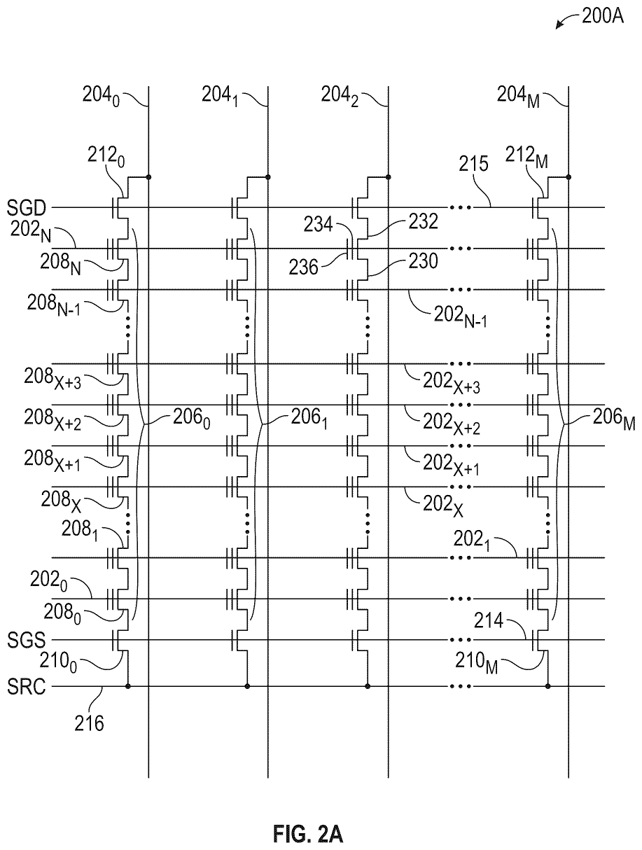

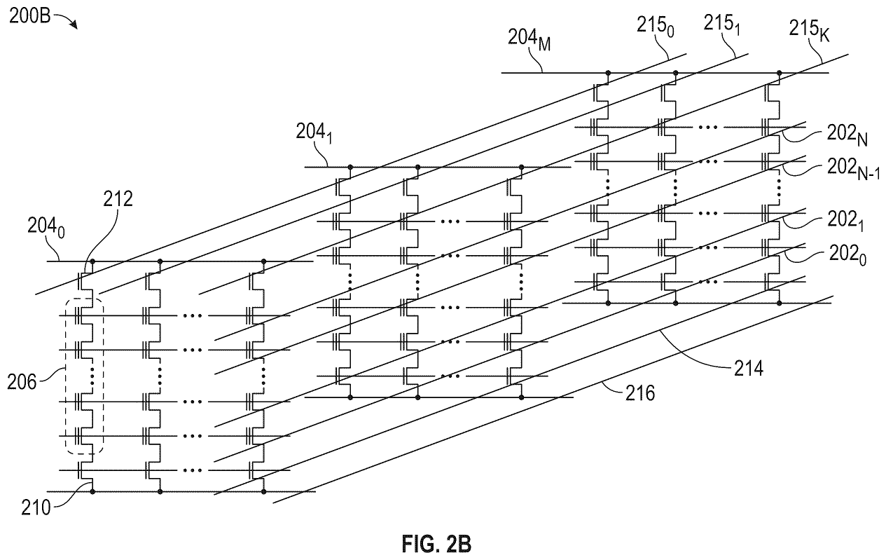

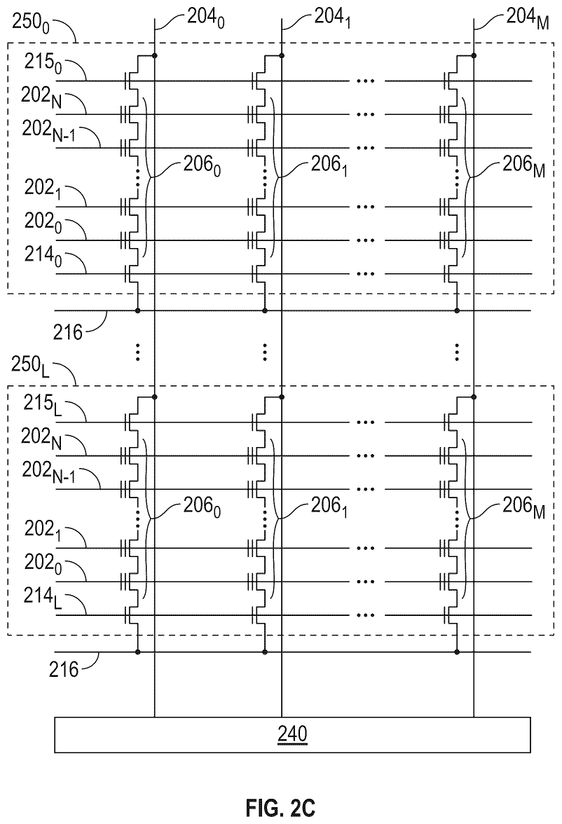

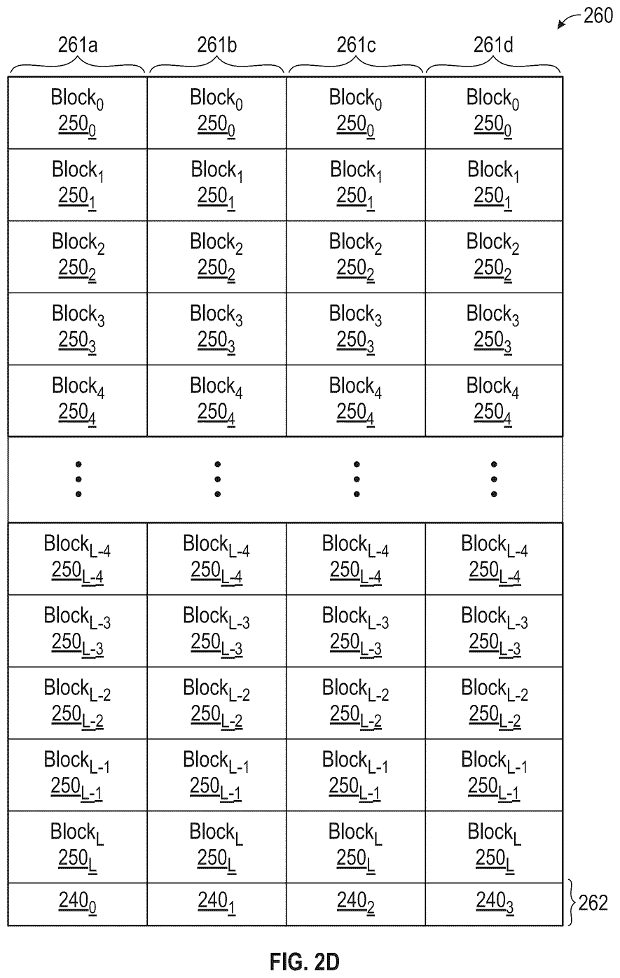

FIGS. 2A-2B are example schematics of portions of an array of memory cells 200A, such as a NAND memory array. Array of memory cells 200A may be an example of memory array 104 of a memory device 130 as described with reference to FIG. 1C according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to select line 214.

The drain of each select gate 212 can be connected to bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device described with reference to FIG. 1B, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

As described above, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L}, can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204.

FIG. 2D is a block schematic of a portion of an example array of memory cells 260. Array of memory cells 260 can be used as array 104 in a memory device 130 described with reference to FIG. 1C. The array of memory cells 260 is depicted as having four memory planes 261 (e.g., memory planes 261a-261d). Each of the memory planes 261 can correspond to planes 165 depicted in FIG. 1A. Each memory plane 261 can be in communication with a respective buffer portion 240, which can collectively form a page buffer 262. Page buffer 262 may be used to implement page buffer 152 shown in FIG. 1C. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

With continued reference to FIGS. 1C and 2A-2C, during a true erase operation (during which memory cells are actually being erased), the local controller 135 (e.g., using an erase operation manager 137) can cause a common source voltage line, e.g., the SRC 216 (FIG. 2A), to be ramped to an erase voltage (VERA) with an erase pulse while the select gates 210₀ to 210_{M} (SGS transistors) are turned on. Ramping to this high bias erase voltage, and the subsequent recovery from this voltage ramping, may take a significant amount of time. Concurrently, the erase operation manager 137 can cause the select gates 212₀ to 212ₘ (FIG. 2A) to be turned off to enable the drains of the select gates 2120 to 212m to float, which causes the bit lines 204₀ to 204_{M} to also float. Further, the erase operation manager 137 can couple the word lines 202 (FIG. 2A) to ground, e.g., zero volts, or retain the word lines 202 at a low voltage. This set of voltage levels at the memory array 200A can create an erase potential that causes the memory cells 208₀ to 208_{N} to be erased, e.g., forces electrons to exit through a body of each memory cell and out the floating bit lines 204₀ to 204_{M}. In other embodiments, the reverse can be done so the select gates 210₀ to 210_{M} are turned off, causing the SRC line 216 to float while the voltage of the bit lines are ramped to Vera while the select gates 212₀ to 212_{M} are turned on. As mentioned earlier, in 3D NAND, one of the channel region, pillar, or bit line can also be ramped up in voltage to cause erasure of attached memory cells. Thus, for simplicity herein, reference to “memory line” should be understood to make reference to any of the SRC line or bit lines in 2D NAND or to any of channel, pillar, or bit lines in 3D NAND. In some embodiments, one or more sub-blocks, to include a physical block, of memory cells are erased during the same true erase operation. A block of memory cells can be generally understood to include four or more sub-blocks, wherein each sub-block includes a separate string of memory cells.

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

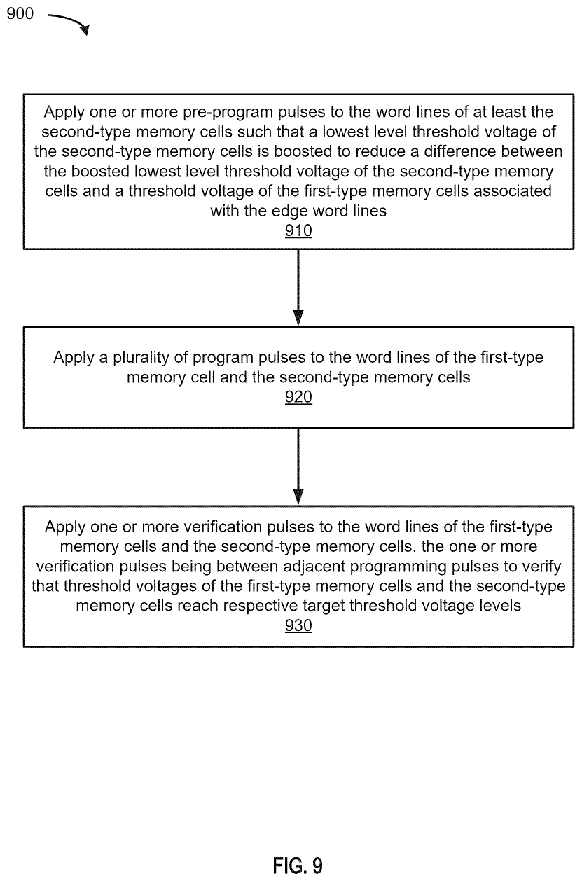

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least FIG. 9, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system (e.g., host system 105 shown in FIG. 1A) that includes, is coupled to, or utilizes a memory system (e.g., memory system 110 of FIG. 1A). Apparatus 300 can be used to perform operations of a controller (e.g., to execute an operating system to perform operations corresponding to host system controller 106 and/or local controller 135 of FIG. 1A).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., host system controller 106 and/or local controller 135 of FIG. 1A). The computer program instructions 324 may be stored in data storage device 320, or other computer-readable medium, and loaded into main memory device 330 when execution of the computer program instructions is desired. For example, processor 310 may be used to implement one or more components and systems described herein, such as host system controller 106 and/or local controller 135 (shown in FIG. 1A). Thus, the method steps of at least FIG. 9 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least FIG. 9. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using memory system 110 (FIG. 1A) described herein. In some examples, data storage device 320 and main memory device 330 may include one or more memory devices 130 (FIG. 1A).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

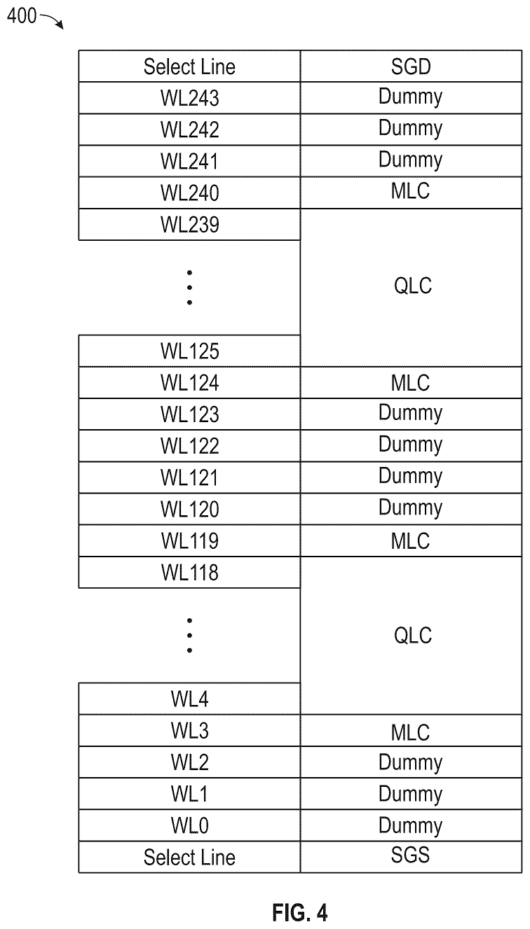

FIG. 4 is a block diagram illustrating a word line configuration of a memory block 400 in a memory device in accordance with some embodiments of the present disclosure. In one embodiment, block 400 represents a portion of memory arrays 200A or 200B, as shown in FIGS. 2A-2B. As illustrated in FIG. 4, block 400 can include a number of word lines WL0-WL243, arranged in a vertical stack. These word lines can, for example, represent some portion of word lines 202₀ to 202_{N} as shown in FIGS. 2A-2B. In one embodiment, block 400 further includes a select line coupled to a source select gate device (SGS) at the bottom of the vertical stack and a select line coupled to a drain select gate device (SGD) at the top of the vertical stack. Each of the word lines WL0-WL243 can be coupled to one or more memory cells which form vertical memory strings in block 400 surrounding pillars of channel material, and can receive control signals to perform memory access operations on the associated memory cells. Depending on the embodiment, block 400 can include some other number of word lines and/or select lines.

In one embodiment, word lines WL0-WL2, WL120-WL123, and WL241-WL243 are referred to as dummy word lines and are generally not used for storing data. Word lines WL3-WL119 and WL124-WL240 can be referred to as data word lines which are used for storing data (e.g., host data or system data). Memory block 400 can be arranged in a quasi-two-dimensional or a three-dimensional memory array as illustrated in FIGS. 2A and 2B. In one embodiment, the data word lines are arranged into two contiguous decks, separated by dummy word lines WL120-WL123. The data word lines in each deck can generally be coupled to memory cells configured to operate as higher-level memory (with higher data density), such as QLC memory for example, as compared to lower-level memory (with lower data density), such as MLC memory for example. In order to improve performance and reliability, the edge data word lines on each deck, such as word lines WL3, WL119, WL124, and WL240 (i.e., the outermost data word lines on each deck immediately adjacent to the surrounding dummy word lines) can be configured to operate as lower-level memory.

The edge data word lines (WL3, WL119, WL124, and WL240) are also referred to as edge MLC word lines in this disclosure. FIG. 4 shows one edge data word line as the outermost data word line on each side of data word lines on each deck. For example, with respect to data word lines WL3-WL119, one edge data word line (WL3 and WL119) is shown on each side thereof. However, it should be understood that in other embodiments, there could be two or more edge data word lines on a side of data word lines. For example, in one embodiment, with respect to data word lines WL3-WL119, there could be two edge data word lines on each side thereof, namely, WL3-WL4 on one side and WL118-WL119 on the other.

In one embodiment, the lower-numbered word lines are on an upper deck, and the higher-numbered word lines are on a lower deck. For example, WL3-WL119 are on the upper deck and WL124-WL240 are on the lower deck. For the word lines on the upper deck, WL4-WL118 are word lines for QLC cells. The two QLC word lines on the edges, namely, WL4 and WL118, are referred to as edge QLC word lines, while the remaining QLC word lines (WL5-WL117) are referred to as non-edge QLC word lines. Likewise, WL125 and WL239 are the two edge QLC word lines on the lower deck, and WL126-WL238 are non-edge QLC word lines.

The terms “QLC word line” or “MLC word line” in this disclosure refer to a word line that connects to a group of memory cells configured to operate at a particular data density (storing different bits of information). For example, a QLC word line connects to a group of memory cells that are configured to store four bits of information, which group of memory cells are sometimes referred to as “QLC cells” in this disclosure. Similarly, an MLC word line connects to a group of memory cells that are configured to store three bits of information, which group of memory cells are sometimes referred as “MLC cells” in this disclosure. However, it should be understood that “QLC cells”, “MLC cells”, “TLC cells”, or “SLC cells” etc., may refer to memory cells of the same structure. The difference is how the cells are being programmed. For example, if a group of memory cells are programmed to store four bits information, they are referred to as “QLC cells”. But if a group of memory cells of the same structure are programmed to store two bits of information, they are referred to as “MLC cells”.

In one embodiment, the lower-numbered word lines are on a lower deck, and the higher-numbered word lines are on an upper deck. Control logic, such as local controller 135-a of memory device 130-a, as shown in FIG. 1A, can perform a memory access operation, such as a programming operation, on block 400 sequentially starting from a first data word line WL3 at the bottom of the vertical stack to a last data word line WL240 at the top of the vertical stack. Thus, the last data word line WL240 may be disposed on the top of the top deck of data word lines, immediately below the dummy word lines WL241-243 at the top of the vertical stack. WL240 may be the last data word line to be programmed in a sequential programming operation. If, for example, block 400 had some other arrangements of word lines, and/or if the programming operation were to progress from the top down, the last data word line could be some other word lines in the block 400.

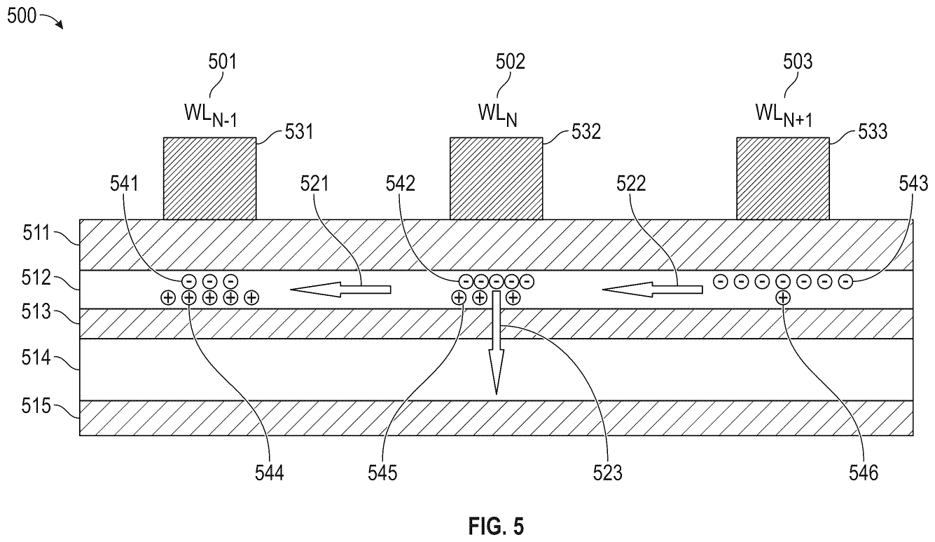

FIG. 5 is a cross-sectional view of three adjacent memory cells in a two-dimensional NAND memory array in accordance with some embodiments of the present disclosure. FIG. 5 depicts how charge loss through lateral charge migration (“LCM”) may occur between adjacent memory cells. Although FIG. 5 illustrates adjacent memory cells in a two-dimensional NAND memory array, it should be understood that charge loss through LCM may occur similarly in a three-dimensional NAND memory array. In view 500, three memory cells 501, 502, and 503 are located on three adjacent data word lines WL_{N-1}, WL_{N}, and WL_{N+1} of the same string, respectively. Control gates 531, 532, and 533 are the respective control gates of the three memory cells. WL_{N-1}, WL_{N}, and WL_{N+1} may represent any of the three consecutive data word lines as shown in FIGS. 2A and 2B, such as word lines 208_{X+1}, 208_{X+2}, and 208_{X+3} of string 206₀. WL_{N-1}, WL_{N}, and WL_{N+1} may also represent any of the three consecutive data word lines as shown in FIG. 4, such as those among word lines WL3-WL119 and WL124-WL240.

In one embodiment, layer 512 refers to a nitride layer (“N layer”), which is the charge storage layer where electrons are trapped or stored to represent the data stored in the memory cell. Layers 511 refers to an oxide layer (“O layer”), which provides insulation between the control gates and the nitride layer. Layer 514 refers to the silicon channel, which is the pathway for the flow of electrons between the source and drain terminals of the memory cells during read and write operations. Layer 513 refers to another oxide layer, which provides insulation between the nitride layer and the silicon channel. Layer 515 refers to the semiconductor substrate.

After programming, electrons of each memory cell are trapped in the nitride layer of the corresponding memory cell. As illustrated in FIG. 5, electrons 541 are trapped in cell 501, electrons 542 are trapped in cell 502, and electrons 543 are trapped in cell 503. Holes 544, 545, and 546 represent locations where an excess of electrons may be trapped or stored in cells 501, 502, and 503, respectively. As illustrated in FIG. 5, there is an equal number of trapped electrons and holes in total in each cell. A cell with a higher number of trapped electrons has fewer holes, whereas a cell with fewer trapped electrons have more holes. For example, cell 501 has the least number of trapped electrons but the greatest number of holes, while cell 503 has the greatest number of trapped electrons but the least number of holes. It is to be noted that the depicted quantities of trapped electrons or holes is for illustration purpose only. The actual numbers of trapped electrons or holes in an actual memory cell are far greater than those indicated in the figure.

The number of trapped electrons stored in the nitride layer of a memory cell corresponds to the threshold voltage level (Vt) of that memory cell, which can be read out during read operations later. More trapped electrons (representing more negative charges) in the nitride layer corresponds to a higher Vt level. On the other hand, fewer trapped electrons in the nitride layer (representing higher positive charge) corresponds to a lower Vt level. In the example illustrated in FIG. 5, among the three memory cells, cell 503 has the highest Vt level because it has the most trapped electrons 543. Cell 501 has the lowest Vt level because it has the least number of trapped electrons 541. The Vt level of cell 502 is in-between the Vt levels of cells 501 and 503.

A programmed memory array may experience charge loss. Charge loss refers to unintended leakage or diffusion of stored electrical charge in a memory cell. Charge loss may lead to inaccuracies in data storage and retrieval, causing data corruption or loss. There are at least two kinds of charge loss, namely, vertical loss (“VL”) and lateral charge migration (“LCM”). With respect to cell 502 for example, vertical loss (along arrow 523) refers to trapped electrons 542 vertically penetrating the oxide layer 513 into the silicon channel 514 and flow away during memory read/write operations.

Lateral charge migration refers to trapped electrons in the nitride layer of one memory cell migrating to the nitride layers of memory cells on nearby word lines on the same string. LCM is mainly caused by trapped electrons being attracted by positive charges in adjacent memory cells. As illustrated in FIG. 5, trapped electrons 542 of cell 502 may migrate to cell 501 along arrow 521, and trapped electrons 543 of cell 503 may migrate to cell 502 along arrow 522. When there are holes in adjacent memory cells on both sides, trapped electrons of the memory cells in the middle tend to migrate to the side that has higher positive charges (or more holes). For example, trapped electrons 542 of WL_{N} may migrate laterally to WL_{N-1} (along arrow 521) instead of to WL_{N+1} because cell 501 has more positive holes than cell 503. As having more positive holes (or fewer trapped electrons) correspond to lower Vt, more LCM charge loss may occur in a memory cell when the Vt of an adjacent cell is lower, or in other words, when the voltage difference of Vt between the two adjacent cells is higher. For example, when the Vt of cell 502 is at L15 and the Vt of cell 501 is at L0, more LCM charge loss (migrating to cell 501 along arrow 521) may occur at cell 502.

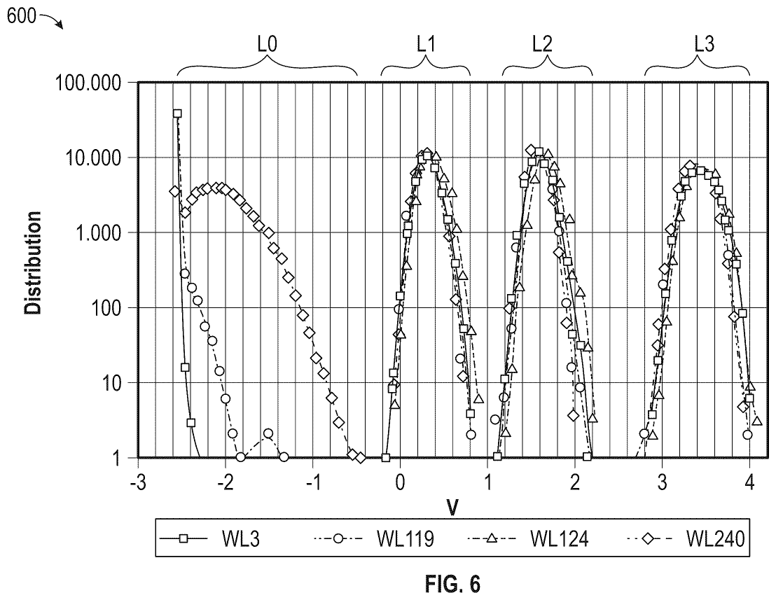

FIG. 6 illustrates a Vt distribution chart for four edge MLC word lines of memory block 400 after a regular programing operation in accordance with some embodiments of the present disclosure. In chart 600, the x-axis represents the Vt levels for four edge MLC word lines WL3, WL119, WL124, and WL240 in a memory array, e.g., memory arrays 200A or 200B represented by memory block 400. The y-axis represents the distribution of threshold voltage Vt among multiple memory cells of each word line. Chart 600 shows Vt distributions in four levels (L0 to L3) for MLC cells. Each level represents a range, which is indicated in the four braces (L0 to L3) on the top of the chart. As shown in FIG. 6, after a regular programing operation, Vt waveforms at levels L1-L3 for all the four edge MLC word lines overlap and are distributed relatively evenly. However, Vt waveforms at level L0 for the three lower-numbered edge MLC word lines (WL3, WL119, WL124) are considerably lower, leaving a larger gap between L0 and L1. For example, for WL3, the Vt value at L0 is around −2.5 mV. For WL119, the Vt value at L0 is around −2.0 mV. For WL124, the Vt value at L0 is lower than −3.0 mV and therefore not shown in the chart. On the other hand, the Vt value at L0 for WL240 is around −1.0 mV, which is considerably higher than that of the other three edge MLC word lines. In some embodiments, when WL240 is the last word line to be programmed, and when the memory array is programed sub-block by sub-block, the Vt level of the last word line (in this case WL240) can be higher because of inhibit operations.

This phenomenon, characterized by a substantially lower Vt value at L0 for certain edge MLC word lines, may not manifest in QLC word lines. For example, referring back to FIG. 4, non-edge QLC word lines WL5-WL118 and WL126-WL238 may not exhibit such a phenomenon. One reason of this phenomenon is because, for memory cells in the central segment of data word lines, trapped electrons may migrate laterally in both directions and could potentially compensate the lost electrons in adjacent cells. For example, referring back to FIG. 5, with respect to cell 502, while some trapped electrons 542 may have migrated to cell 501 (along arrow 521), some trapped electrons 543 in cell 503 may have also migrated to cell 502 (along arrow 522). This may supplement some lost electrons in cell 502 so that the Vt level of cell 502 can be maintained. However, consider WL_{N} as an edge MLC word line with no WL_{N+1}, then the Vt level of cell 502 would decrease because while its trapped electrons may migrate to cell 501, the lost electrons cannot be compensated from the other side. Consequently, the Vt levels at L0 for memory cells on the edge MLC word lines are typically low, with the exception of the last edge MLC word line to be programmed.

As a result of the phenomenon illustrated in FIG. 6, the first three edge QLC word lines (WL4, WL118, and WL125) in block 400 may experience more LCM charge loss than the non-edge QLC word lines because the Vt differences between them and the three adjacent edge MLC word lines (WL3, WL119, and WL124) are higher. This higher LCM charge loss poses a significant challenge for a memory array to meet its Read Window Budget (RWB) requirements under High Temperature Data Retention (HTDR) tests.

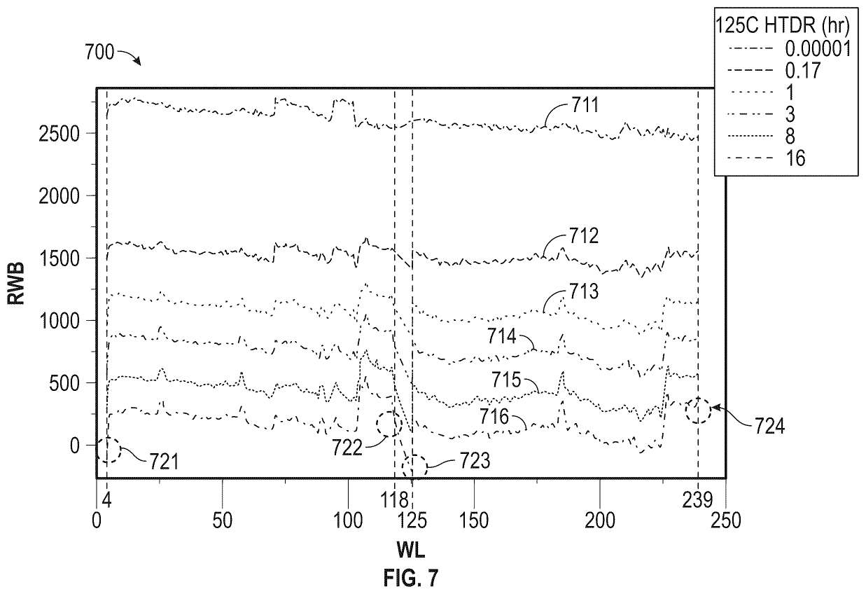

FIG. 7 illustrates Read Window Budgets of memory cells across all data word lines in a memory array under High Temperature Data Retention test in accordance with some embodiments of the present disclosure. In chart 700, the x-axis represents word lines from WL0 to WL250 in a memory array, e.g., memory arrays 200A or 200B represented by memory block 400. The y-axis represents the total RWB for each word line under different HTDR tests. RWB is the sum of margins among threshold voltages (Vt) for all the levels. For example, referring back to FIG. 6, the RWB of a MLC cell is the sum of all three margins, i.e., the margin between L0/L1, the margin between L1/L2, and the margin between L2/L3. Likewise, RWB of a QLC cell is the sum of all the fifteen margins among levels L0 and L15, i.e., between L0/L1, L1/L2, . . . , and L14/L15. In the design of memory arrays, larger RWB is preferred because a larger RWB for memory cells provides enough margins between different Vt levels, so that the cell levels may be read correctly in the event of excessive charge loss or disturbance/over-program.

Chart 700 shows the RWBs of word lines after all the word lines in memory arrays 200A or 200B are being programed. Curve 711 represents the RWBs of all the word lines under room temperature. Curves 712-716 represents the RWBs of all the word lines after the temperature is increased to 125° C., but for different durations under the HTDR test. For example, curve 712 represents RWBs after the memory array is placed (or baked) in 125° C. for 0.17 hours, and curve 713 represents RWBs after the memory array is baked in 125° C. for 1 hour, and so on. Curve 716s represents an end-of-life situation, showing RWBs after the memory array is baked in 125° C. for 16 hours. The RWBs decrease significantly when the baked duration increases. For example, as illustrated in FIG. 7, while the RWBs under room temperature are as high as around 2,500 mV (curve 711), the RWBs after the memory array is being baked for 16 hours are only at around 250 mV (curve 716).

This inverse correlation between RWBs and temperature/duration of exposure can be attributed to several factors. One such reason is that with increasing temperature or prolonged exposure to elevated temperatures, the level of charge loss escalates as trapped electrons become more mobile and active. When charge loss increases, the Vt waveforms for each threshold voltage level (e.g., L0-L3 for MLC, and L0-L15 for QLC) shift downwards and widens, making the margins between different levels narrower, thus resulting in decrease of total RWB.

However, as illustrated in FIG. 7, the RWBs are not evenly decreased for all the word lines when the temperature or bake duration increases. There is an abrupt drop on the first three edge QLC word lines (WL4, WL118, and WL125). Take curve 716 for example, there is an abrupt drop in RWB on WL4 (as compared to WL5), marked by reference 721 in the chart. Similarly, reference 722 indicates an abrupt drop in RWB on WL118 (as compared to WL117), and reference 723 indicates an abrupt drop in RWB on WL125 (as compared to WL126). No significant drop, however, at reference 724, which represents RWB on the last edge QLC word line WL239 (as compared to WL238).

An abrupt RWB decrease on the first three edge QLC word lines (WL4, WL118, and WL125) indicates that these word lines are experiencing significantly more charge loss compared to non-edge QLC word lines, which is likely due to LCM. As previously explained in FIG. 5, more LCM charge loss may occur in a memory cell when the Vt of an adjacent cell is much lower. Also as previously explained in FIG. 6, the Vt waveforms at level L0 for the three lower-numbered edge MLC word lines (WL3, WL119, WL124) are considerably lower. Therefore, memory cells on their neighboring edge QLC word lines WL4, WL118, and WL125 may experience more LCM charge loss than the non-edge QLC word lines. This abrupt decrease of RWB on some edge QLC word lines may significantly impact the performance of a memory array and its ability to meet certain specification requirements. To improve the RWB on edge QLC word lines, the Vt levels at L0 of their adjacent edge MLC cells need to be boosted to reduce the voltage difference between the MLC cells and the QLC cells on edge QLC word lines. The Vt levels at L0 may be boosted to a higher voltage but still within the range of L0. For example, referring back to FIG. 6, the Vt value at L0 for WL3 is around −2.5 mV, which is at the lower end of range L0. This value may be boosted to be within the middle or upper end of range L0, e.g., to around −1.5 mV or −0.5 mV, to reduce the voltage difference between the MLC cells on WL3 and their adjacent QLC cells. This newly boosted voltage level is sometimes referred to in this disclosure as the “target voltage” or “target level”. In other embodiments, the Vt levels at L0 may be boosted into higher ranges, e.g., to be within the range of L1, L2, or L3.

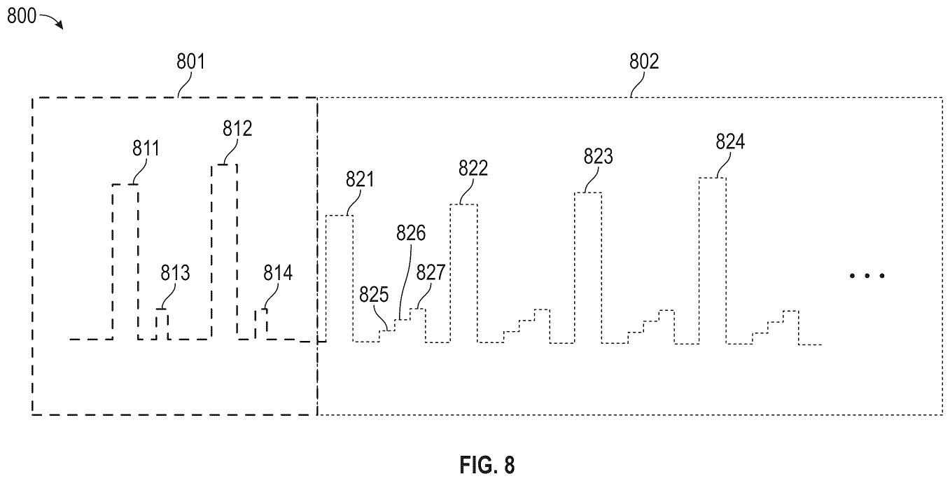

FIG. 8 illustrates a program sequence applied to MLC memory cells on some edge MLC word lines in a memory array, e.g., memory arrays 200A or 200B represented by memory block 400 in accordance with some embodiments of the present disclosure. Program sequence 800 includes a pre-program sequence 801, followed by a regular program sequence 802. Pre-program sequence 801 can be performed by a memory controller, e.g., local controller 135-a, to program the concerned edge MLC word lines, e.g., the first three edge MLC word lines WL3, WL119, and WL124 of block 400, but not the last edge MLC word line WL240. Regular program sequence 802 can be performed by the memory controller to program all the data word lines. Depending on the embodiments, which are explained in more detail below, pre-program sequence 801 can be applied to some or all the sub-blocks of memory block 400, while regular program sequence 802 can be applied sub-block by sub-block. In some embodiments, prior to the pre-program sequence 801, the memory controller performs a memory erase operation.

In one embodiment, during pre-program sequence 801, the memory controller applies one or more pre-program Vpgm pulses 811 and/or 812 to one of the first three edge MLC word lines (WL3, WL119, or WL124). This is to boost the lowest level threshold voltage (e.g., L0 Vt level) of the MLC cells to a target voltage, so that the voltage difference between the MLC cells and their adjacent QLC cells on edge QLC word lines can be reduced. It is to be noted that although two pre-program Vpgm pulses are shown in FIG. 8, they are for illustrative purposes only. In some embodiments, more than two pre-program Vpgm pulses may be applied in pre-program sequence 801 to boost the L0 Vt level of the MLC cell to a target voltage.

In one embodiment, following a pre-program Vpgm pulse, the memory controller applies a pre-program verification pulse (e.g., pulse 813 or 814) to verify if the boosted lowest level threshold voltage has reached a target level. If the target level has not been reached, the memory controller may apply additional pre-program Vpgm pulses. In one embodiment, two or more consecutive pre-program Vpgm pulses may be applied before a pre-program verification pulse is applied.

In one embodiment, during pre-program sequence 801, no pre-program verification pulse is applied after pre-program Vpgm pulse. A pre-program Vpgm pulse without pre-program verification pulse is sometimes referred to as a blind pulse. A blind pulse Vpgm is determined by an offset from a trimmed Vpgm for base QLC. As such, this reduces the L0 Vt variation from die to die. Using separate trims for each edge MLC word line also provides individual controllability to compensate VgVt differences. Using the blind pulse method can reduce operation time and provide a simple and cost-effective approach to improve data retention of edge QLC word lines.

After the pre-program sequence 801, the memory controller performs regular program sequence 802. During the regular program sequence 802, the memory controller selects the data word lines that contain the MLC and/or QLC cells to be programmed. Then, the memory controller applies a plurality of regular-program Vpgm pulses (e.g., pulses 821-824) to the control gate of each memory cell on the selected word line. These pulses comprise specific voltage levels and durations designed to gradually increase the charge in the floating gate.

After each regular-program Vpgm pulse, the memory controller applies one or more regular-program verification pulses (e.g., pulses 825-827) to the word lines being programmed. This is to verify whether the target threshold voltage levels in the MLC cells being programmed have been reached. The verification involves reading the state of the memory cell to check if it corresponds to the intended data state. If the verification indicates that the desired state has not been achieved, additional regular-program Vpgm pulses can be applied. As indicated by the regular-program pulses 822-824 and their subsequent regular-verification pulses, this program-verification process is repeated until the desired programming level for the MLC cell is reached.

In one embodiment, program sequence 800 is repeated and performed until all the memory cells in one sub-block are programed. The same sequence is then repeated sub-block by sub-block, until all the sub-blocks are programed. In another embodiment, pre-program sequence 801 is first performed on all the sub-blocks. Then, regular program sequence 802 is repeated and performed sub-block by sub-block. Such pre-program sequence 801 is sometimes referred to as the “ganged program”. During the ganged program, a pre-program Vpgm pulse (e.g., 811) is applied on all the edge MLC cells of all the sub-blocks (with no inhibit cells). Then, a pre-program verification pulse (e.g., pulse 813) is applied to verify if all the edge MLC cells of all the sub-blocks have reached the target L0 Vt level. If not all the cells have reached the target level, the passing cells are inhibited and the next pre-program pulse (e.g., pulse 812) is applied. The ganged program repeats until all the edge MLC cells of all the sub-blocks in the memory block have reached the target L0 Vt level.

In yet another embodiment, pre-program sequence 801 can be first performed on a selected group of sub-blocks. For example, for a memory block 400 that has four sub-blocks, individually referred to as sub0, sub1, sub2, and sub3, pre-program sequence 801 can be first performed on sub-blocks sub0 and sub3, followed by regular program sequence 802 being repeated and performed on each of the sub-blocks sub0 and sub3. Next, pre-program sequence 801 can then be performed on sub-blocks sub1 and sub2, followed by regular program sequence 802 being repeated and performed on each of the sub-blocks sub1 and sub2.

In yet another embodiment, regular program sequence 802 is performed first to program the MLC cells on edge MLC word lines. After that, pre-program sequence 801 is performed to boost L0 Vt level of the MLC cells on edge MLC word lines.

As previously explained, program sequence 800 can be applied to the two edge MLC word lines of each deck, except to the last edge MLC word line of the last deck to be programmed in a sequential programming operation (WL240). In one embodiment, program sequence 800 can also be applied to the last edge MLC word line of the last deck to be programmed.

Referring back to FIG. 4, edge MLC word lines (WL3, WL119, WL124, and WL240) are generally of a memory type (hereinafter “the second-type”) that has a lower storage level than the memory type of the rest of the data word lines, such as WL4-WL118 and WL125-WL239 (hereinafter “the first-type”). For example, in one embodiment, the first-type memory cells can be QLCs and the second-type memory cells can be MLCs. In another embodiment, the first-type memory cells can be TLCs and the second-type memory cells can be SLCs. In yet another embodiment, the first-type memory cells can be QLCs and the second-type memory cells can be SLCs. In yet another embodiment, the first-type memory cells can be TLCs and the second-type memory cells can be MLCs. In yet another embodiment, the first-type memory cells are of the same type as the second-type memory cells. In yet another embodiment, the first-type memory cells are of the type that has a lower storage level than the second-type memory cells.

In one embodiment, the second-type word lines are dummy word lines. For example, referring back to FIG. 4, WL3, WL119, WL124 and WL240 are dummy word lines instead of MLC word lines. They are immediately adjacent to the first-type word lines, and are referred to as the “edge dummy word lines” in this disclosure. During pre-program sequence 801, the memory controller applies one or more pre-program Vpgm pulses to edge dummy word lines to boost the threshold voltage of the memory cells on these word lines, so that the voltage difference between the edge dummy word lines and their adjacent first-type word lines can be reduced.

FIG. 9 illustrates a flowchart showing methods that support techniques for improving data retention of edge word lines in accordance with some embodiments of the present disclosure. Method 900 may be performed by a memory device, or memory controllers in a memory device, such as host system controller 106, memory system controller 115, and/or local controllers 135-a or 135-b. In some embodiments, method 900 can be implemented in the form of firmware that is stored in computer readable medium and executed by local controller 135 to cause the memory device 130 to perform the operations described herein. The memory device comprises first-type memory cells (e.g., QLC cells) and second-type memory cells (e.g., MLC cells). The first-type memory cells have edge word lines (e.g., edge QLC word lines) and non-edge word lines (e.g., non-edge QLC word lines). The edge word lines of the first-type memory cells (e.g., edge QLC word lines) border with the word lines of the second-type memory cells (e.g., edge MLC word lines).

Method 900 includes step 910, in which a memory controller causes word line drivers to apply one or more pre-program pulses to the word lines of at least the second-type memory cells such that a lowest level threshold voltage of the second-type memory cells is boosted to reduce a difference between the boosted lowest level threshold voltage of the second-type memory cells and a threshold voltage of the first-type memory cells associated with the edge word lines. Referring back to FIG. 8, in pre-program sequence 801, the memory controller causes word line drivers to apply one or more pre-program Vpgm pulses 811 and/or 812 to one of the first three edge MLC word lines (WL3, WL119, or WL124). This is to boost the lowest level threshold voltage (e.g., L0 Vt level) of the MLC cells on the first three edge MLC word lines. Consequently, the voltage difference between the MLC cells and their adjacent QLC cells on edge QLC word lines can be reduced. In one embodiment, only one pre-program Vpgm pulse 811 is applied. In other embodiments, two or more Vpgm pulses may be applied to boost the L0 Vt level to a target voltage.

Referring still to FIG. 9, method 900 further includes step 920, in which a memory controller causes word line drivers to apply a plurality of program pulses to the word lines of the first-type memory cell and the second-type memory cells. Referring back to FIG. 8, regular program sequence 802 is applied during the programming of memory cells on all the data word lines in the memory block (including all the MLCs and the QLCs). During the regular program sequence 802, the memory controller selects the target data word line that contains the memory cells to be programmed. Then, the memory controller causes word line drivers to apply a plurality of regular-program Vpgm pulses (e.g., pulses 821-824) to the control gate of each memory cell on the selected word line.

Referring still to FIG. 9, method 900 further includes step 930, in which a memory controller causes word line drivers to apply one or more verification pulses to the word lines of the first-type memory cells and the second-type memory cells. The one or more verification pulses are between adjacent program pulses, and they are to verify that threshold voltages of the first-type memory cells and the second-type memory cells reach respective target threshold voltage levels. Referring back to FIG. 8, after each regular-program Vpgm pulse, the memory controller causes word line drivers to apply one or more regular-program verification pulses (e.g., pulses 825-827) to the word lines being programmed in step 910 (e.g., MLC and QLC word lines). This is to verify whether the target threshold voltage levels in the memory cells being programmed (MLCs or QLCs) have been reached. If the verification indicates that the target threshold voltage levels have not been achieved, the memory controller may apply additional regular-program Vpgm pulses. This program-verification process is repeated until the target threshold voltage levels for the memory cell have been reached.

Other methods may be used to boost the lowest level threshold voltage (e.g., L0 Vt level) of the MLC cells on edge MLC word lines for the purpose of reducing the voltage difference between the MLC cells and their adjacent QLC cells on edge QLC word lines. In one embodiment, L0 Vt of the MLC cells on edge MLC word lines can be boosted by the memory controller applying no seeding when programming the edge MLC word lines. No seeding may cause poorer boosting and more program disturbance. However, it can also result in a higher L0 Vt level in the MLC cells.

In one embodiment, L0 Vt of the MLC cells on edge MLC word lines can be boosted by the memory controller applying higher VsGD to allow larger leakage current through boosting. Poor boosting may cause more program disturbance. However, it can also result in a higher L0 Vt level in the MLC cells.

In one embodiment, L0 Vt of the MLC cells on edge MLC word lines can be maintained at a higher level by not completely erasing the MLC cells on the edge MLC word lines. As explained previously, in some embodiments, prior to the pre-program sequence 801, the memory controller performs a memory erase operation. Referring back to FIG. 5, during a regular erase operation, the memory controller applies a high voltage (e.g. 20V) to silicon channel 514 and a low voltage (e.g., 0V) to the control gates (e.g., control gates 531, 532, etc.). Applying 0V to the control gates helps create a larger voltage potential difference between the control gate and the silicon channel, so that trapped electrons in memory cells may be erased completely. However, when performing the erase operation on edge MLC word lines, the memory controller may apply a voltage higher than 0V to the control gates, creating a relatively smaller voltage potential difference between the control gate and the silicon channel. In this way, the trapped electrons in the MLC cells on edge MLC word lines are not erased completely and the L0 Vt level in these cells can be maintained at a higher level.

In one embodiment, L0 Vt of the MLC cells on edge MLC word lines can be boosted by applying Vpass on edge MLC word lines during a neighboring word line programming or during the programming of all word lines. High Vpass causes disturbance on L0 Vt of the MLC cells (similar to read disturb) for program bit lines. Inhibiting bit lines has much less effect due to channel boosting.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
a memory array comprising a first-type memory cells and a second-type memory cells, the first-type memory cells having edge word lines and non-edge word lines, wherein the edge word lines of the first-type memory cells border word lines of the second-type memory cells; and
a memory controller operatively coupled to the memory array, the memory controller being configured to perform operations comprising:
applying one or more pre-program pulses to the word lines of at least the second-type memory cells such that a lowest level threshold voltage of the second-type memory cells is boosted to reduce a difference between the boosted lowest level threshold voltage of the second-type memory cells and a threshold voltage of the first-type memory cells associated with the edge word lines, and
applying a plurality of program pulses to the word lines of the first-type memory cell and the second-type memory cells; and
applying one or more verification pulses to the word lines of the first-type memory cells and the second-type memory cells, the one or more verification pulses being between adjacent program pulses to verify that threshold voltages of the first-type memory cells and the second-type memory cells reach respective target threshold voltage levels.

2. The memory device of claim 1, wherein the memory controller is further configured to perform operations comprising:
subsequent to applying at least one pre-program pulse, applying one or more verification pulses to verify that the boosted lowest level threshold voltage reaches a target level.

3. The memory device of claim 1, wherein the one or more pre-program pulses are applied to a block of the memory array, the block of the memory array comprising a plurality of sub-blocks.

4. The memory device of claim 1, wherein the one or more pre-program pulses are applied to a selected group of sub-blocks of the memory array.

5. The memory device of claim 1, wherein the first-type memory cells are at a storage level higher than that of the second-type memory cells.

6. The memory device of claim 5, wherein the first-type memory cells are quad-level cells and the second-type memory cells are multi-level cells.

7. The memory device of claim 5, wherein the first-type memory cells are triple-level cells and the second-type memory cells are single-level cells.

8. The memory device of claim 5, wherein the first-type memory cells are quad-level cells and the second-type memory cells are single-level cells.

9. The memory device of claim 5, wherein the first-type memory cells are triple-level cells and the second-type memory cells are multi-level cells.

10. The memory device of claim 1, wherein the second-type memory cells are memory cells of dummy word lines.

11. A method performed by a memory device, the memory device comprising a first-type memory cells and a second-type memory cells, the first-type memory cells having edge word lines and non-edge word lines, wherein the edge word lines of the first-type memory cells border word lines of the second-type memory cells, the method comprising:
applying one or more pre-program pulses to the word lines of at least the second-type memory cells such that a lowest level threshold voltage of the second-type memory cells is boosted to reduce a difference between the boosted lowest level threshold voltage of the second-type memory cells and a threshold voltage of the first-type memory cells associated with the edge word lines, and
applying a plurality of program pulses to the word lines of the first-type memory cell and the second-type memory cells; and
applying one or more verification pulses to the word lines of the first-type memory cells and the second-type memory cells, the one or more verification pulses being between adjacent program pulses to verify that threshold voltages of the first-type memory cells and the second-type memory cells reach respective target threshold voltage levels.

12. A memory device comprising:
an input/output (I/O) circuit;
a memory array coupled to the I/O circuit, the memory array comprising a first-type memory cells and a second-type memory cells, the first-type memory cells having edge word lines and non-edge word lines, wherein the edge word lines of the first-type memory cells border word lines of the second-type memory cells;
a memory controller configured to control the memory array and the I/O circuit to perform operations comprising:
applying one or more pre-program pulses to the word lines of at least the second-type memory cells such that a lowest level threshold voltage of the second-type memory cells is boosted to reduce a difference between the boosted lowest level threshold voltage of the second-type memory cells and a threshold voltage of the first-type memory cells associated with the edge word lines, and
applying a plurality of program pulses to the word lines of the first-type memory cell and the second-type memory cells; and
applying one or more verification pulses to the word lines of the first-type memory cells and the second-type memory cells, the one or more verification pulses being between adjacent program pulses to verify that threshold voltages of the first-type memory cells and the second-type memory cells reach respective target threshold voltage levels.

13. The memory device of claim 12, wherein the memory controller is further configured to perform operations comprising:
subsequent to applying at least one pre-program pulse, applying one or more verification pulses to verify that the boosted lowest level threshold voltage reaches a target level.

14. The memory device of claim 12, wherein the one or more pre-program pulses are applied to a block of the memory array, the block of the memory array comprising a plurality of sub-blocks.

15. The memory device of claim 12, wherein the one or more pre-program pulses are applied to a selected group of sub-blocks of the memory array.

16. The memory device of claim 12, wherein the first-type memory cells are at a storage level higher than that of the second-type memory cells.

17. The memory device of claim 16, wherein the first-type memory cells are quad-level cells and the second-type memory cells are multi-level cells.

18. The memory device of claim 16, wherein the first-type memory cells are triple-level cells and the second-type memory cells are single-level cells.

19. The memory device of claim 16, wherein the first-type memory cells are quad-level cells and the second-type memory cells are single-level cells.

20. The memory device of claim 16, wherein the first-type memory cells are triple-level cells and the second-type memory cells are multi-level cells.

21. The memory device of claim 16, wherein the second-type memory cells are memory cells of dummy word lines.

22. A system comprising:
a processor;
a first memory controller; and
a memory device coupled to the processor and the first memory controller, wherein the memory device comprises:
a memory array comprising a first-type memory cells and a second-type memory cells, the first-type memory cells having edge word lines and non-edge word lines, wherein the edge word lines of the first-type memory cells border word lines of the second-type memory cells; and
a second memory controller operatively coupled to the memory array, the second memory controller being configured to perform operations comprising:
applying one or more pre-program pulses to the word lines of at least the second-type memory cells such that a lowest level threshold voltage of the second-type memory cells is boosted to reduce a difference between the boosted lowest level threshold voltage of the second-type memory cells and a threshold voltage of the first-type memory cells associated with the edge word lines, and
applying a plurality of program pulses to the word lines of the first-type memory cell and the second-type memory cells; and
applying one or more verification pulses to the word lines of the first-type memory cells and the second-type memory cells, the one or more verification pulses being between adjacent program pulses to verify that threshold voltages of the first-type memory cells and the second-type memory cells reach respective target threshold voltage levels.

23. The system of claim 22, wherein the second memory controller is further configured to perform operations comprising:
subsequent to applying at least one pre-program pulse, applying one or more verification pulses to verify that the boosted lowest level threshold voltage reaches a target level.

24. The system of claim 22, wherein the one or more pre-program pulses are applied to a block of the memory array, the block of the memory array comprising a plurality of sub-blocks.

25. The system of claim 22, wherein the one or more pre-program pulses are applied to a selected group of sub-blocks of the memory array.
